(19) United States
(12) Patent Application Publication
(10) Pub. No.: US 2024/0287674 A1
(43) Pub. Date: Aug. 29, 2024

(54) COMPOSITE FILM APPLIED TO FLEXIBLE SUBSTRATE, PREPARATION METHOD THEREFOR, AND PRODUCT THEREOF

(71) Applicant: JIANGSU FAVORED NANOTECHNOLOGY CO., LTD., Wuxi (CN)

(72) Inventor: Jian ZONG, Wuxi (CN)

(73) Assignee: JIANGSU FAVORED NANOTECHNOLOGY CO., LTD., Wuxi (CN)

(21) Appl. No.: 18/572,516

(22) PCT Filed: May 13, 2022
(86) PCT No.: PCT/CN2022/092787

§ 371 Date: Dec. 20, 2023

(30) Foreign Application Priority Data
Jun. 22, 2021 (CN) 202110693705.6

(51) Int. Cl. C23C 16/26; C09D 183/04; C23C 16/02; C23C 16/455; C23C 16/50

(52) U.S. Cl. CPC C23C 16/26; C09D 183/04; C23C 16/0227; C23C 16/45557; C23C 16/50

(57) ABSTRACT

A composite film applied to a flexible substrate, a preparation method thereof, and a product thereof are provided. The composite film applied to the flexible substrate is used for being formed on the surface of the flexible substrate. The composite film applied to the flexible substrate includes: a nano-transition layer, which is a film layer formed on the surface of the flexible substrate by plasma enhanced chemical vapor deposition using a siloxane monomer as a reaction raw material; and a diamond-like carbon film, which is a film layer formed on the surface of the nano-transition layer by plasma enhanced chemical vapor deposition using a carbon source gas as a reaction raw material. The surface hardness and friction resistance of the substrate can be improved, and requirements of a flexible display device are met.

### CROSS-REFERENCE TO RELATED APPLICATIONS

This application claims the benefit of priority to Chinese Patent Application No. 202110693705.6, filed on Jun. 22, 2021, and entitled “COMPOSITE FILM APPLIED TO FLEXIBLE SUBSTRATE, PREPARATION METHOD THEREFOR, AND PRODUCT THEREOF”, the contents of which are incorporated herein by reference in their entirety.

### TECHNICAL FIELD

The present disclosure relates to the field of nano coating technology, and more particularly, to a composite film applied to a flexible substrate, a preparation method thereof and a product thereof.

### BACKGROUND

In recent years, transparent plastics have been widely developed and applied due to their excellent optical properties, and advantageous properties such as low density, easy processing and molding, good impact resistance, and foldability. For example, liquid crystal display (LCD) devices, organic light-emitting diode (OLED) devices and other display devices are widely used in smart electronic products, such as smartphones, tablet personal computers, and various wearable devices, which demand ultra-thinness, lightness, foldability, and convenience. Although a flexible touch screen with a large area can bring a qualitative leap in electronic products' appearance and easy operation, in order to protect this flexible touch screen type display panel from external scratches and impacts, it is necessary to attach a layer of protective cover on it.

At present, a hardened glass is used on a general display screen as a cover, but due to the heavy weight of the glass material itself, easy to break by external impacts, and unable to achieve a certain level of bending, so highly transparent organic polymer materials have become a substitute with great prospects. However, these transparent plastics have a poor solvent resistance, a poor weather resistance, a low hardness, and are particularly prone to scratches in friction, which greatly limits the further expansion in application areas. In addition, as substitutes for glass materials, these polymer plastics need to realize similar properties of glass, such as high transparency, temperature resistance, insulation, and low coefficient of thermal expansion. Currently available optically transparent flexible cover materials generally include colorless polyimide (CPI), polyethylene naphthalate (PEN), polyethylene terephthalate (PET), polymethylmethacrylate (PMMA), polycarbonate (PC), polystyrene (PS), and so on.

However, due to their own intrinsic defects, such as low surface hardness and water-oxygen barrier properties, polymer plastics used as a protective cover may lead to the failure of the display device. Therefore, as a flexible cover material, there is still much room for improvement in wear resistance and sealing performance, etc. The common technical means on the market is to coat the surface of these polymer covers with composite resin composites to make up for the shortcomings of physical properties. On the one hand, a simple organic hardened layer cannot achieve a hardness comparable to that of a glass cover, and on the other hand, in order to improve the scratch resistance of the cover as much as possible, it is generally necessary to increase the thickness of the organic hardened layer, which leads to a lengthened curing time, resulting in more pronounced curling of the material due to shrinkage during the curing of the hardening adhesive. At the same time, a relatively thick organic hardened layer is prone to film peeling and cracking, and also leads to a significant reduction in bending resistance. Therefore, with the rapid development in the field of transparent plastics, simply increasing the thickness of the organic hardened layer to achieve scratch resistance of the flexible cover will be difficult to meet the increasingly demanding market needs.

### SUMMARY

According to an advantage of the present disclosure, a composite film applied to a flexible substrate, a preparation method thereof and a product thereof are provided to improve the surface hardness and friction resistance of the flexible substrate and help meet the needs of flexible display devices.

According to an embodiment of the present disclosure, another advantage of the present disclosure is that the composite film applied to the flexible substrate can effectively avoid a curing process of a hardening adhesive, thereby avoiding shrinkage and curling problems.

According to an embodiment of the present disclosure, another advantage of the present disclosure is that the composite film applied to the flexible substrate has a good compactness, thereby ensuring a scratch-resistant performance at a relatively low thickness, while also avoiding cracking caused by bending at an excessive thickness.

According to an embodiment of the present disclosure, another advantage of the present disclosure is that the composite film applied to the flexible substrate can be prepared by PECVD technology under the same process conditions, which greatly simplifies the process.

According to an embodiment of the present disclosure, another advantage of the present disclosure is that the composite film applied to the flexible substrate can combine a compactness of a nano-transition layer and a high hardness and smoothness of a diamond-like carbon film, so that excellent scratch resistance and excellent bending performance can be achieved even if the thickness of the composite film is maintained within 2 um.

According to another advantage of the present disclosure, there is no need to use expensive materials or complex structures to achieve the above objects. Therefore, the present disclosure successfully and effectively provides a solution, which provides a simple composite film applied to a flexible substrate, a preparation method thereof and a product thereof, and also increases the practicability and the reliability of the flexible substrate, the preparation method and the product.

For achieving at least one of the above advantages or other advantages and objects, the present disclosure provides a composite film applied to a flexible substrate, for being formed on a surface of a flexible substrate, and the composite film applied to the flexible substrate includes:
a nano-transition layer, which is a film layer formed on the surface of the flexible substrate by plasma enhanced chemical vapor deposition using a siloxane monomer as a reaction raw material; and
a diamond-like carbon film, which is a film layer formed on a surface of the nano-transition layer by plasma enhanced chemical vapor deposition using a carbon source gas as a reaction raw material.

According to an embodiment of the present disclosure, the nano-transition layer is composed of a silicon element, an oxygen element, a carbon element and a hydrogen element.

According to an embodiment of the present disclosure, a thickness of the nano-transition layer ranges from 500 nm to 2000 nm.

According to an embodiment of the present disclosure, the siloxane monomer is a linear siloxane compound or a cyclic siloxane compound.

According to an embodiment of the present disclosure, the siloxane monomer has a following structure:

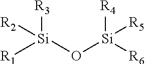

wherein each of R₁ to R₆ independently represents a C₁-C₆ alkyl, a C₂-C₆ alkenyl, or a hydrogen, and at least one of R₁ to R₆ does not represent a hydrogen.

According to an embodiment of the present disclosure, the siloxane monomer has a following structure:

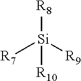

wherein each of R₇ to R₁₀ independently represents a C₁-C₆ alkyl, a C₁-C₆ alkoxy, a C₂-C₆ alkenyl, or a hydrogen, with the proviso that at least one of R₇ to R₁₀ does not represent a hydrogen, and at least one of R₇ to R₁₀ includes an oxygen to form a silicon-oxygen bond.

According to an embodiment of the present disclosure, the siloxane monomer has a following structure:

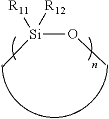

wherein n represents 3, 4, 5, or 6, and each of R₁₁ and R₁₂ independently represents a C₁-C₆ alkyl, a C₂-C₆ alkenyl, or a hydrogen, with the proviso that at least one of R₁₁ and R₁₂ does not represent a hydrogen.

According to an embodiment of the present disclosure, the siloxane monomer includes one or more selected from a group consisting of: octamethylcyclotetrasiloxane, hexamethylcyclotrisiloxane, tetramethylcyclotetrasiloxane, trimethylcyclotrisiloxane, tetramethyltetravinylcyclotetrasiloxane, dodecamethylcyclohexasiloxane, decamethylcyclopentasiloxane, dimethylsiloxane, tetraethoxysilane, tetramethoxysilane, allyltrimethoxysilane, hexamethyldisiloxane, tetramethyldisiloxane, and hexaethyldisiloxane.

According to an embodiment of the present disclosure, the diamond-like carbon film is a hydrogen-containing amorphous carbon layer and composed of sp²-hybridized and sp³-hybridized carbon, and the flexible substrate is made of a material including one or more selected from a group consisting of: polyimide, polyethylene naphthalate, polyethylene terephthalate, polymethyl methacrylate, polycarbonate, and polystyrene.

According to an embodiment of the present disclosure, the carbon source gas includes one or more selected from a group consisting of: methane, propane, acetylene, and benzene.

According to an embodiment of the present disclosure, a thickness of the diamond-like carbon film ranges from 3 nm to 30 nm.

According to another aspect of the present disclosure, a preparation method of a composite film applied to a flexible substrate is further provided, and includes steps of:
depositing a nano-transition layer on a surface of the flexible substrate by plasma enhanced chemical vapor deposition using a siloxane monomer as a reaction raw material; and
depositing a diamond-like carbon film on a surface of the nano-transition layer by plasma enhanced chemical vapor deposition using a carbon source gas as a reaction raw material.

According to an embodiment of the present disclosure, depositing the nano-transition layer on the surface of the flexible substrate by plasma enhanced chemical vapor deposition using the siloxane monomer as the reaction raw material includes steps of:
after placing the flexible substrate in a reaction chamber of a PECVD device, introducing a plasma source gas, and using plasmas generated by glow discharge to perform a plasma bombardment cleaning on the surface of the flexible substrate; and
after the plasma bombardment cleaning, sequentially introducing an inert gas and the siloxane monomer to deposit the nano-transition layer on the surface of the flexible substrate by plasma enhanced chemical vapor deposition.

According to an embodiment of the present disclosure, depositing the nano-transition layer on the surface of the flexible substrate by plasma enhanced chemical vapor deposition using the siloxane monomer as the reaction raw material further includes a step of
before placing the flexible substrate in the reaction chamber, purging the surface of the flexible substrate clean with a dry gas.

According to an embodiment of the present disclosure, the plasma source gas is oxygen.

According to an embodiment of the present disclosure, in the step of plasma bombardment cleaning, a flow rate of the plasma source gas ranges from 50 sccm to 300 sccm; a pressure of the reaction chamber ranges from 2 Pa to 8 Pa; an ICP source power ranges from 500 W to 1000 W; a bias power supply is set to range from 500V to 1000V; and a duration time of the bombardment cleaning ranges from 5 min to 20 min.

According to an embodiment of the present disclosure, in the step of depositing the nano-transition layer, a flow rate of the inert gas ranges from 50 sccm to 300 sccm; a flow rate of the siloxane monomer ranges from 500 uL/min to 1500 uL/min; a pressure of the reaction chamber ranges from 5 Pa to 15 Pa; an ICP source power ranges from 500 W to 1000 W; a bias power is set to range from 300V to 800V; and a duration time for coating ranges from 60 min to 240 min.

According to an embodiment of the present disclosure, the step of depositing the diamond-like carbon film on the surface of the nano-transition layer by plasma enhanced chemical vapor deposition using the carbon source gas as the reaction raw material includes steps of.
pumping out impurity gases of siloxane reaction in the reaction chamber of the PECVD device until the pressure in the reaction chamber reaches a predetermined pressure threshold; and
introducing an inert gas and the carbon source gas to deposit the diamond-like carbon film on the surface of the nano-transition layer by plasma enhanced chemical vapor deposition.

According to an embodiment of the present disclosure, in the step of depositing the diamond-like carbon film, a flow rate of the inert gas ranges from 50 sccm to 200 sccm; a flow rate of the carbon source gas ranges from 20 sccm to 100 sccm; a pressure of the reaction chamber ranges from 4 Pa to 8 Pa; an ICP source power ranges from 300 W to 1000 W; a bias power is set to range from 200V to 600V; and a duration time for coating ranges from 1 min to 30 min.

According to an embodiment of the present disclosure, the predetermined pressure threshold is 1 Pa.

According to another aspect of the present disclosure, a product is further provided. The product includes:
a flexible substrate; and
a composite film applied to the flexible substrate, which is formed on a surface of the flexible substrate and includes:
a nano-transition layer, which is a film layer formed on the surface of the flexible substrate by plasma enhanced chemical vapor deposition using a siloxane monomer as a reaction raw material; and
a diamond-like carbon film, which is a film layer formed on the surface of the nano-transition layer by plasma enhanced chemical vapor deposition using a carbon source gas as a reaction raw material.

According to an embodiment of the present disclosure, the flexible substrate is a polymer transparent plastic.

According to an embodiment of the present disclosure, the flexible substrate is made of a material including one or more selected from a group consisting of polyimide, polyethylene naphthalate, polyethylene terephthalate, polymethyl methacrylate, polycarbonate, and polystyrene.

According to an embodiment of the present disclosure, the flexible substrate is a flexible display device.

Objects and advantages of the present disclosure will be more fully appreciated with reference to the following description.

These and other objects, features and advantages of the present disclosure are fully realized by the following detailed description and claims.

### BRIEF DESCRIPTION OF THE DRAWINGS

FIG. 1 schematically illustrates a structural diagram of a composite film applied to a flexible substrate according to an embodiment of the present disclosure;

FIG. 2 schematically illustrates a flow chart of a preparation method of the composite film applied to the flexible substrate according to an embodiment of the present disclosure;

FIG. 3 schematically illustrates a flow chart of a step in the preparation method of the composite film applied to the flexible substrate according to an embodiment of the present disclosure;

FIG. 4 schematically illustrates a flow chart of another step in the preparation method of the composite film applied to the flexible substrate according to an embodiment of the present disclosure;

FIG. 5 schematically illustrates a diagram of the performance test results of the composite films applied to flexible substrates and prepared in Embodiments 1-4 and Comparative Embodiments 1-5; and

FIG. 6 schematically illustrates a structural diagram of a product configured with a composite film applied to a flexible substrate according to an embodiment of the present disclosure.

### DETAILED DESCRIPTION

The following description serves to disclose the present disclosure to enable those skilled in the art to practice the present disclosure. The embodiments in the following description are only for exemplification. Those skilled in the art may think of other obvious variations. The basic principles of the present disclosure as defined in the following description may be applied to other embodiments, variations, modifications, equivalents, and other technical solutions without departing from the spirit and scope of the present disclosure.

It will be appreciated that the term “a”, “an”, or “one” is to be understood as “at least one” or “one or more”, i.e., in one embodiment, the number of one element may be one and in another embodiment the number of one element may be multiple, and that the term “a”, “an”, or “one” is not to be construed to limit the number.

The present disclosure provides a composite film applied to a flexible substrate, a preparation method thereof and a product thereof, and innovatively uses PECVD (Plasma Enhanced Chemical Vapor Deposition) vacuum coating technology to deposit a nano-transition layer on a flexible substrate (such as a polymer plastic cover), and then a transparent and smooth DLC (diamond-like carbon) film layer as an outermost layer. It effectively avoids a coating and curing process of a hardening adhesive, thereby avoiding shrinkage and curling phenomena. Due to a high compactness of the vacuum nanofilm layer, a scratch-resistant performance at a relatively low thickness is ensured, and cracking phenomenon caused by bending at an excessive thickness is avoided, thereby helping meet the needs of display devices such as flexible display devices.

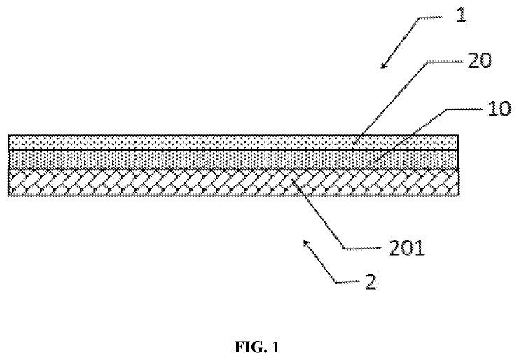

Specifically, with reference to FIG. 1 of the accompanying drawings of the present disclosure, a composite film 1 applied to a flexible substrate according to an embodiment of the present disclosure is illustrated. The composite film 1 applied to a flexible substrate is suitable for being formed on a surface of a flexible substrate 2, and the composite film 1 applied to a flexible substrate may include a nano-transition layer 10 and a diamond-like carbon film 20. The nano-transition layer 10 is a film layer formed on the surface of the flexible substrate 2 by plasma enhanced chemical vapor deposition using a siloxane monomer as a reaction raw material. The diamond-like carbon film 20 is a film layer formed on the surface of the nano-transition layer 10 by plasma enhanced chemical vapor deposition using a carbon source gas as a reaction raw material.

It should be noted that the nano-transition layer 10 and the diamond-like carbon film 20 of the composite film 1 applied to a flexible substrate of the present disclosure are both prepared by PECVD technology under the same process conditions, which greatly simplifies the process. In the meantime, the nano-transition layer 10 may be composed of Si (silicon), O (oxygen), C (carbon), H (hydrogen) and other elements, and has a good compactness. The diamond-like carbon film 20 may be implemented as a hydrogen-containing amorphous carbon layer, mainly composed of sp²-hybridized and sp³-hybridized carbon, and has high hardness and smoothness performances. Therefore, the composite film 1 applied to the flexible substrate can greatly improve the surface hardness and wear resistance of the flexible substrate 2.

In other words, the composite film 1 applied to the flexible substrate may be composed of the nano-transition layer 10 and the diamond-like carbon film 20, and the nano-transition layer 10 is formed between the flexible substrate 2 and the diamond-like carbon film 20. A thickness of the composite film 1 applied to the flexible substrate only needs to be maintained within 2 um to achieve excellent scratch resistance. At the same time, the composite film 1 applied to the flexible substrate has excellent bending resistance, and no curing process is required during the entire process. Therefore, the composite film 1 applied to the flexible substrate can effectively prevent the flexible substrate 2 from curling or warping.

According to an embodiment of the present disclosure, the siloxane monomer may be a linear siloxane compound, and may also be a cyclic siloxane compound.

Exemplarily, the siloxane monomer may have the following structure.

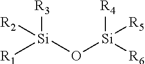

In the structure, each of R₁ to R₆ independently represents a C₁-C₆ alkyl, a C₂-C₆ alkenyl, or a hydrogen, and at least one of R₁ to R₆ does not represent a hydrogen. Optionally, each of R₁ to R₆ independently represents a C₁-C₃ alkyl, a C₂-C₄ alkenyl, or a hydrogen, for example, methyl, ethyl, vinyl, allyl or hydrogen, provided that at least one of R₁ to R₆ does not represent a hydrogen. Optionally, at least two or three (e.g., four, five, or six) of R₁ to R₆ do not represent a hydrogen. Optional examples may include hexamethyldisiloxane (HMDSO), hexaethyldisiloxane, tetramethyldisiloxane (TMDSO), 1,3-divinyltetramethyldisiloxane (DVTMDSO) and hexavinyldisiloxane (HVDSO).

According to another embodiment of the present disclosure, the siloxane monomer may also have the following structure.

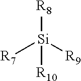

In the structure, each of R₇ to R₁₀ independently represents a C₁-C₆ alkyl, a C₁-C₆ alkoxy, a C₂-C₆ alkenyl, or a hydrogen, with the proviso that at least one of R₇ to R₁₀ does not represent a hydrogen, and at least one of R₇ to R₁₀ includes an oxygen to form a silicon-oxygen bond. Optionally, each of R₇ to R₁₀ independently represents a C₁-C₃ alkyl, a C₁-C₃ alkoxy, a C₂-C₄ alkenyl, or a hydrogen, with the proviso that at least one of R₇ to R₁₀ does not represent a hydrogen. Optionally, at least two, for example, three or four, of R₇ to R₁₀ do not represent a hydrogen. Optional examples may include allyltrimethoxysilane (ATMOS), tetraethylorthosilicate (TEOS), 3-(diethylamino)propyl-trimethoxysilane, trimethylsiloxane, triisopropylsiloxane, tetramethoxysilane, and dimethylsiloxane.

According to another embodiment of the present disclosure, the siloxane monomer may have the following structure.

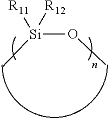

In the structure, n represents 3, 4, 5, or 6, and each of R₁₁ and R₁₂ independently represents a C₁-C₆ alkyl, a C₂-C₆ alkenyl, or a hydrogen, with the proviso that at least one of R₁₁ and R₁₂ does not represent a hydrogen. Optionally, each of R₁₁ and R₁₂ independently represents a C₁-C₃ alkyl, a C₂-C₄ alkenyl, or a hydrogen, for example, methyl, ethyl, vinyl, allyl or hydrogen, provided that at least one of R₁₁ and R₁₂ does not represent a hydrogen. Optional examples may include: trivinyltrimethylcyclotrisiloxane (V₃D₃), tetravinyltetramethylcyclotetrasiloxane (V₄D₄, tetramethylcyclotetrasiloxane (TMCS), octamethylcyclotetrasiloxane (OMCTS), hexamethylcyclotrisiloxane, trimethylcyclotrisiloxane, dodecamethylcyclohexasiloxane, and decamethylcyclopentasiloxane.

According to some embodiments of the present disclosure, the siloxane monomer includes one or more selected from a group consisting of: octamethylcyclotetrasiloxane, hexamethylcyclotrisiloxane, tetramethylcyclotetrasiloxane, trimethylcyclotrisiloxane, tetramethyltetravinylcyclotetrasiloxane, dodecamethylcyclohexasiloxane, decamethylcyclopentasiloxane, dimethylsiloxane, tetraethoxysilane, tetramethoxysilane, allyltrimethoxysilane, hexamethyldisiloxane, tetramethyldisiloxane, and hexaethyldisiloxane.

In addition, as shown in FIG. 1, the flexible substrate 2 may be, but is not limited to be, implemented as a polymer transparent plastic 201 for use in flexible display devices and the like. According to some embodiments, the flexible substrate 2 may be made of a material including, but not limited to, one or more selected from a group consisting of colorless polyimide (CPI), polyethylene naphthalate (PEN), polyethylene terephthalate (PET), polymethyl methacrylate (PMMA), polycarbonate (PC) and polystyrene (PS).

More specifically, according to the above-mentioned embodiments of the present disclosure, the nano-transition layer 10 of the composite film 1 applied to the flexible substrate serves as an intermediate layer, and its thickness may be implemented in a range of 100 nm to 5000 nm. According to some embodiments, a thickness of the nano-transition layer 10 ranges from 500 nm to 2000 nm.

Correspondingly, the diamond-like carbon film 20 of the composite film 1 applied to the flexible substrate is the outermost layer, and its thickness may be implemented in a range of 1 nm to 50 nm. According to some embodiments, a thickness of the diamond-like carbon film 20 ranges from 3 nm to 30 nm.

According to some embodiments, the diamond-like carbon film 20 is implemented as a DLC (diamond-like carbon) nanofilm. It is understandable that, a DLC material is a type of carbon materials, and is non-toxic and environmentally friendly. At the same time, the DLC material also has diamond-like properties, and its surface hardness and wear resistance are excellent. Since the DLC nanofilm covers the nano-transition layer 10, the surface hardness and wear resistance of the entire flexible substrate 2 can be greatly improved.

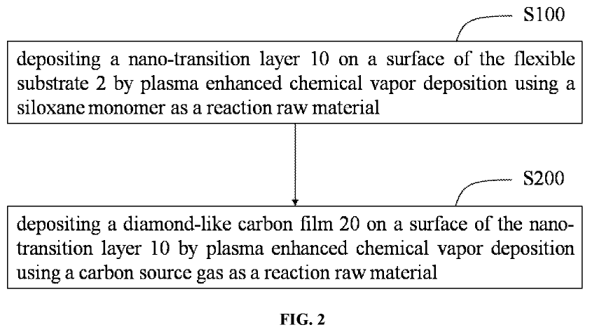

It should be noted that FIG. 2 to FIG. 4 schematically illustrate a preparation method of the composite film applied to the flexible substrate according to an embodiment of the present disclosure. Specifically, as shown in FIG. 2, the preparation method of the composite film applied to the flexible substrate may include steps:

S100: depositing a nano-transition layer 10 on a surface of the flexible substrate 2 by plasma enhanced chemical vapor deposition using a siloxane monomer as a reaction raw material; and

S200: depositing a diamond-like carbon film 20 on a surface of the nano-transition layer 10 by plasma enhanced chemical vapor deposition using a carbon source gas as a reaction raw material.

It should be noted that, in the step S100, before coating to form the nano-transition layer 10, the surface of the flexible substrate 2 is fully subjected to plasma bombardment activation and cleaning treatment, it helps to improve the binding force between substrate and film. The deposition methods of the nano-transition layer 10 and the diamond-like carbon film 20 mainly adopt plasma enhanced chemical vapor deposition (PECVD) coating technology. That is to say, during the processes for respectively preparing the nano-transition layer 10 and the diamond-like carbon film 20, the surface of the flexible substrate 2 and the surface of the nano-transition layer 10 are respectively exposed in a chamber of a plasma enhanced chemical vapor deposition reaction device, plasmas are formed in the chamber, and the nano-transition layer 10 and the diamond-like carbon film 20 are sequentially formed through the deposition reaction of reaction raw materials. The composite film 1 applied to the flexible substrate has excellent film-substrate binding force, hardness and scratch resistance, and the curling of the flexible substrate 2 is effectively inhibited.

It should be understood that, the plasma enhanced chemical vapor deposition (PECVD) process has many advantages over other conventional deposition processes: (1) dry deposition does not need to use organic solvents; (2) an etching effect of the plasma on the surface of the flexible substrate 2 and the surface of the nano-transition layer 10 makes a deposited film have good adhesion with the substrate; (3) the film can be deposited evenly on the surface of an irregular flexible substrate 2 with strong vapor permeability; (4) the film has a good designability, and compared with a micron-level control accuracy of the liquid-phase method, the chemical vapor method can control a thickness of the film in nano scale; (5) the structure of the film is easy to design, the chemical vapor method uses plasma activation, and does not need to design a specific initiator to initiate composite films of different materials, and a variety of raw materials can be combined through adjusting input energy; (6) a good compactness can be achieved, and the chemical vapor deposition method often activates multiple active sites in a process of plasma initiation, which is similar to the scenario in which a molecule has multiple functional groups in solution reaction, and a cross-linked structure is formed between molecular chains through multiple functional groups; (7) as a coating treatment technology, it has excellent universality and wide selection range of coating objects and raw materials used for coating.

Moreover, plasmas may be generated by glow discharge in the plasma enhanced chemical vapor deposition (PECVD) process. The discharge mode includes radio frequency discharge, microwave discharge, intermediate frequency discharge, high frequency discharge, electric spark discharge. The waveforms of the high frequency discharge and the intermediate frequency discharge are sinusoidal or bipolar pulses. Of course, the discharge mode in the plasma enhanced chemical vapor deposition (PECVD) process may be continuous discharge or pulse discharge.

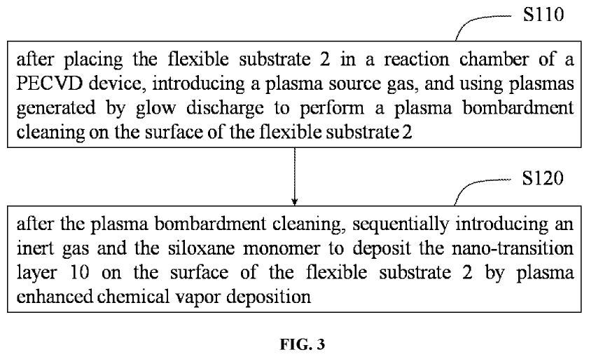

Exemplarily, as shown in FIG. 3, the step S100 of the preparation method of the composite film applied to the flexible substrate according to the above embodiment of the present disclosure may include steps:
S110: after placing the flexible substrate 2 in a reaction chamber of a PECVD device, introducing a plasma source gas, and using plasmas generated by glow discharge to perform a plasma bombardment cleaning on the surface of the flexible substrate 2; and
S120: after the plasma bombardment cleaning, sequentially introducing an inert gas and the siloxane monomer to deposit the nano-transition layer 10 on the surface of the flexible substrate 2 by plasma enhanced chemical vapor deposition.

It should be noted that, before the step S110, a further step may be included: before the flexible substrate 2 is placed in the reaction chamber, purging clean the surface of the flexible substrate 2 with a dry gas. It should be understood that the dry gas may be implemented as, but is not limited to, air or nitrogen.

According to some embodiments, in the step S110, the plasma source gas is oxygen.

According to some embodiments, in the step S110, a flow rate of the plasma source gas ranges from 50 sccm to 300 sccm; a pressure of the reaction chamber ranges from 2 Pa to 8 Pa; an ICP source power ranges from 500 W to 1000 W; a bias power supply is set to range from 500V to 1000V; and a duration time of the bombardment cleaning ranges from 5 min to 20 min.

Correspondingly, in the step S120, the inert gas may be implemented as argon gas.

According to some embodiments, in the step S120, a flow rate of the inert gas ranges from 50 sccm to 300 sccm; a flow rate of the siloxane monomer ranges from 500 uL/min to 1500 uL/min; a pressure of the reaction chamber ranges from 5 Pa to 15 Pa; an ICP source power ranges from 500 W to 1000 W; a bias power is set to range from 300V to 800V; and a duration time for coating ranges from 60 min to 240 min.

It should be noted that, in the step S200, the carbon source gas may be, but is not limited to be, implemented as a hydrocarbon gas such as methane, propane, acetylene or benzene.

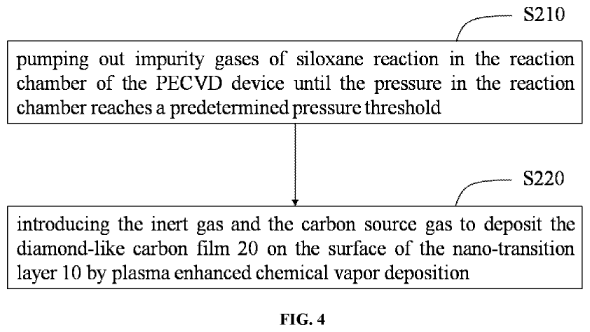

Exemplarily, as shown in FIG. 4, the step S200 of the preparation method of the composite film applied to the flexible substrate according to the above embodiment of the present disclosure may include steps:
S210: pumping out impurity gases of siloxane reaction in the reaction chamber of the PECVD device until the pressure in the reaction chamber reaches a predetermined pressure threshold; and
S220: introducing the inert gas and the carbon source gas to deposit the diamond-like carbon film 20 on the surface of the nano-transition layer 10 by plasma enhanced chemical vapor deposition.

It should be noted that, in the step S210, the impurity gases of siloxane reaction may include plasma generated during the coating process in the step S100 and the remaining siloxane monomer.

According to some embodiments, in the step S210, the predetermined pressure threshold is implemented as 1 Pa.

Correspondingly, in the step S220, the carbon source gas may be, but is not limited to be, implemented as one or more selected from a group consisting of methane, propane, acetylene and benzene. The inert gas may be implemented as, but is not limited to, helium, argon, xenon, and the like. It may be understood that the inert gas may be the above-mentioned single gas or a mixed gas of the above-mentioned single gas. For example, the inert gas is a mixed gas of helium and argon.

According to some embodiments, in the step S220, a flow rate of the inert gas ranges from 50 sccm to 200 sccm; a flow rate of the carbon source gas ranges from 20 sccm to 100 sccm; a pressure of the reaction chamber ranges from 4 Pa to 8 Pa; an ICP source power ranges from 300 W to 1000 W; a bias power is set to range from 200V to 600V; and a duration time for coating ranges from 1 min to 30 min.

It should be understood that, according to an embodiment, the specific implementation method of the preparation method of the composite film applied to the flexible substrate is as follows:
1) cleaning the surface of the flexible substrate 2 such as a flexible polymer membrane material with a dry gas (e.g., air or nitrogen);
2) placing the substrate 2 in a reaction chamber of a PECVD device, and pumping out impurity gases in the reaction chamber by a vacuum pump set;
3) when the pressure reaches 1 Pa or below, introducing oxygen at a flow rate ranging from 50 sccm to 300 sccm, controlling the pressure in the reaction chamber in a range of 2 Pa to 8 Pa, turning on an ICP source to provide a power ranging from 500 W to 1000 W, setting the bias power supply of the substrate rotator to range from 500V to 1000V, and performing a bombard cleaning for 5-20 minutes to clean the surface impurities of the flexible substrate 2, thereby obtaining a highly active surface and providing an excellent substrate for subsequent film formation;
4) thereafter, turning off the power supply, then introducing argon gas at a flow rate ranging from 50 sccm to 300 sccm, introducing the siloxane monomer into the chamber through an evaporator at a flow rate controlled to range from 500 μL/min to 1500 μL/min, controlling the pressure in the chamber in a range of 5 Pa to 15 Pa, setting the ICP source power to range from 500 W to 1000 W, setting the bias power supply to range from 300V to 800V, performing the coating for 60-240 minutes, and then turning off the power supply, the gas source and the monomer diaphragm valve in sequence;
5) pumping out the impurity gases of siloxane reaction, when the pressure in the reaction chamber reaches 1 Pa or below, introducing a carbon source gas (such as methane, propane, acetylene, benzene and other hydrocarbon gas sources) at a flow rate ranging from 20 sccm to 100 sccm, introducing an inert gas (such as argon, helium, etc.) at a flow rate ranging from 50 sccm to 200 sccm, maintaining the pressure at a range of 4 Pa to 8 Pa, setting the ICP power to range from 300 W to 1000 W, setting the bias voltage to range from 200V to 600V, performing the coating for 1-10 minutes, then turning off the power supply, the gas source and the pump set in sequence, and opening the chamber door to take out the sample.

It should be noted that, according to some embodiments of the present disclosure, the flexible substrate 2 is implemented as a polymer transparent plastic 201 as an example to illustrate the advantages and features of the composite film 1 applied to the flexible substrate, in some other embodiments of the present disclosure, the flexible substrate 2 may also be implemented as products that require coating, such as flexible display screens or mobile phones. The present disclosure is further described in detail below through specific embodiments. It should be noted that the following embodiments are intended to facilitate the understanding of the present disclosure and do not limit it in any way.

### Embodiment 1

In this embodiment, the thickness of the nano-transition layer 10 of the composite film 1 applied to the flexible substrate was 500 nm, and the thickness of the diamond-like carbon film 20 was 15 nm.

The composite film 1 applied to the flexible substrate may be prepared according to the following steps:

1) A PET substrate with a thickness of 50 μm was purged clean with dry nitrogen, the substrate was placed in a reaction chamber, and impurity gases were pumped out the vacuum chamber by a vacuum pump set. When the pressure reached 1 Pa or below, oxygen was introduced at a flow rate of 100 sccm, and the pressure in the vacuum chamber was controlled at 6 Pa. An ICP source was turned on to provide a power of 800 W, the bias power supply of the substrate rotator was set to 800V, and a bombard clean was performed for 15 minutes.

2) Thereafter, the power supply was turned off, then argon gas was introduced at a flow rate of 100 sccm, the siloxane monomer was introduced into the chamber through an evaporator at a flow rate controlled to range from 500 μL/min to 1500 μL/min, and the pressure in the chamber was controlled at 10 Pa. The ICP source power was set to 700 W, the bias power supply was set to 500V, and a transition layer with a thickness of 500 nm was formed. Then the power supply, the gas source and the monomer diaphragm valve were turned off in sequence.

3) The impurity gases of siloxane reaction were pumped out. When the pressure in the reaction chamber reached 1 Pa or below, methane was introduced at a flow rate of 50 sccm, argon was introduced at a flow rate of 50 sccm, and the pressure was maintained at 5 Pa. The ICP power was set to 600 W, the bias voltage was set to 500V, and a DLC film layer with a thickness of 15 nm was formed. Then the power supply, the gas source and the pump set were turned off in sequence, and the chamber door was opened to take out the sample.

### Embodiment 2

In this embodiment, the thickness of the nano-transition layer 10 of the composite film 1 applied to the flexible substrate was 1000 nm, and the thickness of the diamond-like carbon film 20 was 15 nm.

The composite film 1 applied to the flexible substrate may be prepared according to the following steps: compared with the preparation process of the nano-transition layer 10 in the above Embodiment 1, the coating time was extended so that the thickness of the nano-transition layer 10 reached 1000 nm, and other processes remained unchanged. The thickness of the diamond-like carbon film 20 was still 15 nm, and its preparation process remained unchanged, compared to the preparation process of the diamond-like carbon film 20 described in Embodiment 1.

### Embodiment 3

In this embodiment, the thickness of the nano-transition layer 10 of the composite film 1 applied to the flexible substrate was 1500 nm, and the thickness of the diamond-like carbon film 20 was 15 nm.

The composite film 1 applied to the flexible substrate may be prepared according to the following steps: compared with the preparation process of the nano-transition layer 10 in the above Embodiment 1, the coating time was extended so that the thickness of the nano-transition layer 10 reached 1500 nm, and other processes remained unchanged. The thickness of the diamond-like carbon film 20 was still 15 nm, and its preparation process remained unchanged, compared to the preparation process of the diamond-like carbon film 20 described in Embodiment 1.

### Embodiment 4

In this embodiment, the thickness of the nano-transition layer 10 of the composite film 1 applied to the flexible substrate was 1500 nm, and the thickness of the diamond-like carbon film 20 was 15 nm.

Compared with Embodiment 3, the PET substrate having a thickness of 50 μm was replaced with a CPI substrate having a thickness of 50 μm in Embodiment 4, and the preparation processes of the nano-transition layer 10 and the diamond-like carbon film 20 remained unchanged, compared to the preparation process in Embodiment 3.

### Comparative Embodiment 1

In this comparative embodiment, the thickness of the nano-transition layer 10 of the composite film 1 applied to the flexible substrate was 1500 nm, and the thickness of the diamond-like carbon film 20 was 15 nm.

Compared with Embodiment 1, oxygen was replaced with argon at a flow rate of 100 sccm when bombard cleaning the surface of the substrate in Comparative embodiment 1, and the other coating preparation processes remained unchanged, compared to the preparation process in Embodiment 1.

### Comparative Embodiment 2

In this comparative embodiment, the thickness of the nano-transition layer 10 of the composite film 1 applied to the flexible substrate was 5000 nm, and the thickness of the diamond-like carbon film 20 was 15 nm.

The composite film 1 applied to the flexible substrate may be prepared according to the following steps: compared with the preparation process of the nano-transition layer 10 in the above Embodiment 1, the coating time was further extended so that the thickness of the nano-transition layer 10 reached 5000 nm, and other processes remained unchanged. The thickness of the diamond-like carbon film 20 was still 15 nm, and its preparation process remained unchanged, compared to the preparation process of the diamond-like carbon film 20 described in Embodiment 1.

### Comparative Embodiment 3

In this comparative embodiment, the thickness of the nano-transition layer 10 of the composite film 1 applied to the flexible substrate was 100 nm, and the thickness of the diamond-like carbon film 20 was 15 nm.

The composite film 1 applied to the flexible substrate may be prepared according to the following steps: compared with the preparation process of the nano-transition layer 10 in the above Embodiment 1, the coating time was shortened so that the thickness of the nano-transition layer 10 reached 100 nm, and other processes remained unchanged. The thickness of the diamond-like carbon film 20 was still 15 nm, and its preparation process remained unchanged, compared to the preparation process of the diamond-like carbon film 20 described in Embodiment 1.

### Comparative Embodiment 4

In this comparative embodiment, the thickness of the nano-transition layer 10 of the composite film 1 applied to the flexible substrate was 1500 nm, and the thickness of the diamond-like carbon film 20 was 0 nm.

Compared with Embodiment 4, the preparation process of the diamond-like carbon film 20 was eliminated in Comparative embodiment 4, while the preparation process of the nano-transition layer 10 remained unchanged, compared to the preparation process in Embodiment 4.

### Comparative Embodiment 5

In this comparative embodiment, the thickness of the nano-transition layer 10 of the composite film 1 applied to the flexible substrate was 0 nm, and the thickness of the diamond-like carbon film 20 was 0 nm.

Compared with Embodiment 1, the preparation processes of the nano-transition layer 10 and the diamond-like carbon film 20 were eliminated in Comparative embodiment 5, and only the PET substrate with a thickness of 50 μm was purged clean with dry nitrogen gas.

It should be noted that, the flexible substrates prepared in Embodiments 1-4 and Comparative embodiments 1-5 above were tested for surface pencil hardness, scratch resistance, and dynamic bending performance, wherein the test conditions for scratch resistance and dynamic bending performance were as follows:

1) Scratch resistance test conditions were: a Bonstar #0000 steel wool was provided with a load of 500 g and a speed of 40 cycle/min, the test direction was the same as the fiber direction of the steel wool, the test stroke was 40 mm, and the surface was observed for scratches and recorded every 500 cycles of the test.

2) dynamic bending performance test conditions were: under the conditions that a bending radius (R) was 1.5 mm and a frequency was 30 times/min, the bending position of the film was observed and recorded every 50,000 times of inward bending.

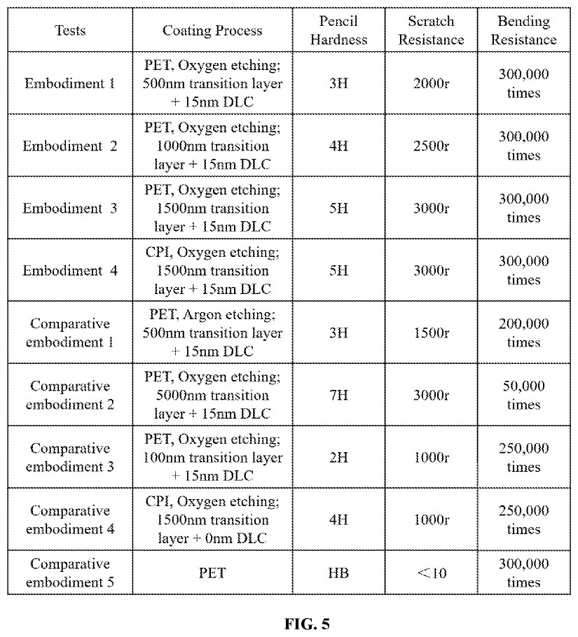

Finally, a list of performance parameters obtained by testing is shown in FIG. 5, and it is clear from the test performance results that the composite film 1 applied to the flexible substrate provided in the present disclosure has significant advantages in comprehensive performance of scratch resistance and bending resistance.

Specifically, comparing Embodiments 1-3 with Comparative embodiments 2, 3, 5, it can be seen that, as the thickness of the nano-transition layer 10 increases, the pencil hardness increases; whereas if the thickness is too small, the pencil hardness is not sufficient, and the scratch resistance performance is not good. If the thickness is too large, the film layer is too brittle, and the bending and folding resistance performance is relatively poor.

Moreover, comparing Embodiment 4 with Comparative embodiment 4, it can be seen that, the diamond-like carbon film 20 can increase the surface hardness and also significantly increases the scratch resistance.

Finally, comparing Embodiment 1 with Comparative embodiment 1, it can be seen that, an appropriate plasma cleaning process has a significant effect on the performance, for example, the plasma treatment with oxygen significantly increases the binding between substrate and film and thus ensures a superior scratch and bending resistance.

It should be noted that, according to an embodiment of the present disclosure, a product configured with the above-described composite film applied to a flexible substrate is further provided. The product includes the composite film 1 applied to a flexible substrate and the flexible substrate 2, and the composite film 1 applied to a flexible substrate is formed on the surface of the flexible substrate 2, resulting in that the product have excellent surface hardness, high abrasion resistance, and high bending resistance.

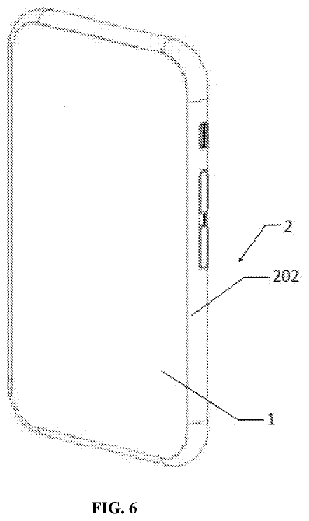

It should be noted that, according to the above embodiments of the present disclosure, as shown in FIG. 6, the flexible substrate 2 may be implemented as a flexible display device 202, so that the surface hardness, the high abrasion resistance, and the high bending resistance thereof are substantially increased. It would be appreciated that the flexible substrate 2 may also be implemented as a transparent flexible cover, wherein the transparent flexible cover is adapted to cover the surface of the flexible display to protect the flexible display.

Of course, in other embodiments of the present disclosure, as shown in FIG. 1, the flexible substrate 2 may be implemented as a polymer transparent plastic 201. For example, the flexible substrate 2 is made of a material including one or more selected from a group consisting of: polyimide, polyethylene naphthalate, polyethylene terephthalate, polymethyl methacrylate, polycarbonate, and polystyrene.

Those skilled in the art will appreciate that, the embodiments of the present disclosure shown in the foregoing description are by way of example only and are not intended to limit the present disclosure. The objects of the present disclosure have been completely and effectively realized. The functionality and structural principles of the present disclosure have been shown and illustrated in the embodiments, and embodiments of the disclosure may be varied or modified without departing from the principles described herein.

1. A composite film applied to a flexible substrate, for being formed on a surface of the flexible substrate, wherein the composite film applied to the flexible substrate comprises:
a nano-transition layer, which is a film layer formed on the surface of the flexible substrate by plasma enhanced chemical vapor deposition using a siloxane monomer as a reaction raw material; and
a diamond-like carbon film, which is a film layer formed on the surface of the nano-transition layer by plasma enhanced chemical vapor deposition using a carbon source gas as a reaction raw material.

2. (canceled)

3. The composite film applied to the flexible substrate according to claim 1, wherein a thickness of the nano-transition layer ranges from 500 nm to 2000 nm.

4. The composite film applied to the flexible substrate according to claim 1, wherein the siloxane monomer is a linear siloxane compound or a cyclic siloxane compound.

5. The composite film applied to the flexible substrate according to claim 4, wherein the siloxane monomer has a following structure: 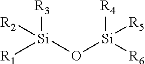
wherein each of R₁ to R₆ independently represents a C₁-C₆ alkyl, a C₂-C₆ alkenyl, or a hydrogen, and at least one of R₁ to R₆ does not represent a hydrogen.

6. The composite film applied to the flexible substrate according to claim 4, wherein the siloxane monomer has a following structure: 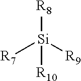
wherein each of R₇ to R₁₀ independently represents a C₁-C₆ alkyl, a C₁-C₆ alkoxy, a C₂-C₆ alkenyl, or a hydrogen, provided that at least one of R₇ to R₁₀ does not represent a hydrogen, and at least one of R₇ to R₁₀ comprises an oxygen to form a silicon-oxygen bond.

7. The composite film applied to the flexible substrate according to claim 4, wherein the siloxane monomer has a following structure: 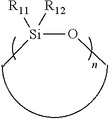
wherein n represents 3, 4, 5, or 6, and each of R₁₁ and R₁₂ independently represents a C₁-C₆ alkyl, a C₂-C₆ alkenyl, or a hydrogen, provided that at least one of R₁₁ and R₁₂ does not represent a hydrogen.

8. The composite film applied to the flexible substrate according to claim 4, wherein the siloxane monomer comprises one or more selected from a group consisting of: octamethylcyclotetrasiloxane, hexamethylcyclotrisiloxane, tetramethylcyclotetrasiloxane, trimethylcyclotrisiloxane, tetramethyltetravinylcyclotetrasiloxane, dodecamethylcyclohexasiloxane, decamethylcyclopentasiloxane, dimethylsiloxane, tetraethoxysilane, tetramethoxysilane, allyltrimethoxysilane, hexamethyldisiloxane, tetramethyldisiloxane, and hexaethyldisiloxane.

9. The composite film applied to the flexible substrate according to claim 1, wherein the diamond-like carbon film is a hydrogen-containing amorphous carbon layer and composed of sp²-hybridized and sp³-hybridized carbon, and the flexible substrate is made of a material comprising one or more selected from a group consisting of: polyimide, polyethylene naphthalate, polyethylene terephthalate, polymethyl methacrylate, polycarbonate, and polystyrene.

10. The composite film applied to the flexible substrate according to claim 9, wherein the carbon source gas comprises one or more selected from a group consisting of: methane, propane, acetylene, and benzene.

11. The composite film applied to the flexible substrate according to claim 9, wherein a thickness of the diamond-like carbon film ranges from 3 nm to 30 nm.

12. A preparation method of a composite film applied to a flexible substrate, wherein the preparation method comprises:
depositing a nano-transition layer on a surface of the flexible substrate by plasma enhanced chemical vapor deposition using a siloxane monomer as a reaction raw material; and
depositing a diamond-like carbon film on a surface of the nano-transition layer by plasma enhanced chemical vapor deposition using a carbon source gas as a reaction raw material.

13. The preparation method of the composite film applied to the flexible substrate according to claim 12, wherein depositing the nano-transition layer on the surface of the flexible substrate by plasma enhanced chemical vapor deposition using the siloxane monomer as the reaction raw material comprises:
after placing the flexible substrate in a reaction chamber of a PECVD device, introducing a plasma source gas, and using plasmas generated by glow discharge to perform a plasma bombardment cleaning on the surface of the flexible substrate; and
after the plasma bombardment cleaning, introducing an inert gas and the siloxane monomer to deposit the nano-transition layer on the surface of the flexible substrate by plasma enhanced chemical vapor deposition.

14. (canceled)

15. The preparation method of the composite film applied to the flexible substrate according to claim 13, wherein the plasma source gas is oxygen.

16. (canceled)

17. The preparation method of the composite film applied to the flexible substrate according to claim 13, wherein during depositing the nano-transition layer, a flow rate of the inert gas ranges from 50 sccm to 300 sccm; a flow rate of the siloxane monomer ranges from 500 uL/min to 1500 uL/min; a pressure of the reaction chamber ranges from 5 Pa to 15 Pa; an ICP source power ranges from 500 W to 1000 W; a bias power is set to range from 300V to 800V; and a duration time for coating ranges from 60 min to 240 min.

18. The preparation method of the composite film applied to the flexible substrate according to claim 12, wherein depositing the diamond-like carbon film on the surface of the nano-transition layer by plasma enhanced chemical vapor deposition using the carbon source gas as the reaction raw material comprises:
pumping out impurity gases of siloxane reaction in the reaction chamber of the PECVD device until a pressure in the reaction chamber reaches a predetermined pressure threshold; and
introducing an inert gas and the carbon source gas to deposit the diamond-like carbon film on the surface of the nano-transition layer by plasma enhanced chemical vapor deposition.

19. The preparation method of the composite film applied to the flexible substrate according to claim 18, wherein during depositing the diamond-like carbon film, a flow rate of the inert gas ranges from 50 sccm to 200 sccm; a flow rate of the carbon source gas ranges from 20 sccm to 100 sccm; a pressure of the reaction chamber ranges from 4 Pa to 8 Pa; an ICP source power ranges from 300 W to 1000 W; a bias power is set to range from 200V to 600V; and a duration time for coating ranges from 1 min to 30 min.

20. The preparation method of the composite film applied to the flexible substrate according to claim 18, wherein the predetermined pressure threshold is 1 Pa.

21. A product, comprising:
a flexible substrate; and
a composite film applied to the flexible substrate as claimed in claim 1, wherein the composite film applied to the flexible substrate is formed on a surface of the flexible substrate.

22. The product according to claim 21, wherein the flexible substrate is a polymer transparent plastic.

23-28. (canceled)
